(19) United States
(12) Patent Application Publication
(10) Pub. No.: US 2013/0019921 A1
(43) Pub. Date: Jan. 24, 2013

(54) STOW STRATEGY FOR A SOLAR PANEL ARRAY

(71) Applicant: THOMPSON TECHNOLOGY INDUSTRIES, INC., Novato, CA (US)

(72) Inventor: Alexander Au, El Cerrito, CA (US)

(73) Assignee: THOMPSON TECHNOLOGY INDUSTRIES, INC., NOVATO, CA (US)

(21) Appl. No.: 13/626,488

(22) Filed: Sep. 25, 2012

Related U.S. Application Data
(63) Continuation-in-part of application No. 12/088,121, filed on Mar. 26, 2008, now Pat. No. 8,273,978.
Application No. 12/088,121 is a continuation-in-part of application No. PCT/US06/38185, filed on Sep. 28, 2006.
(60) Provisional application No. 61/615,170, filed on Mar. 23, 2012.

(51) Int. Cl. H01L 31/042

(52) U.S. Cl. 136/246

(57) ABSTRACT

A solar panel tracking system for simultaneously rotating large arrays of solar panels positioned in multiple rows utilizing a single drive system and having a stow strategy with a stow-and-lock system built into the array support piers. A stow-and-lock stopping structure is mechanically and structurally incorporated into the support piers such that the solar panels stop at approximately 45 degrees, and the stow-and-lock assembly ensures that moment forces of the array are transmitted directly to the immediate support members, obviating the need for the driveline, locking dampers, and rotational supports to resist the forces transmitted from an entire wing and row of panels.

### CROSS REFERENCES TO RELATED APPLICATIONS

The present application claims the benefit of U.S. Provisional Patent Application Ser. No. 61/615,170, filed Mar. 23, 2012 (Mar. 23, 2012), and is also a continuation-in-part of U.S. Utility patent application Ser. No. 12/088,121, filed Mar. 26, 2008 (Mar. 26, 2008), now U.S. Pat. No. 8,273,978, issued Sep. 25, 2012 (Sep. 25, 2012), which application was submitted under 35 U.S.C. 371 based on PCT/US06/38185, filed Sep. 28, 2006 (Sep. 28, 2006), which, in turn, claims the benefit of U.S. Provisional Patent Application Ser. No. 60/721,249, filed Sep. 28, 2005 (Sep. 28, 2005).

### STATEMENT REGARDING FEDERALLY SPONSORED RESEARCH OR DEVELOPMENT

Not applicable.

### THE NAMES OR PARTIES TO A JOINT RESEARCH AGREEMENT

Not applicable.

### INCORPORATION BY REFERENCE OF MATERIAL SUBMITTED ON A COMPACT DISC

Not applicable.

### BACKGROUND OF THE INVENTION

1. Field of the Invention

This invention relates generally to the collection of solar energy for conversion into electrical energy, and more specifically to the arrangement of solar panel drive and tilt mechanisms to follow the movement of the sun relative to the earth. Still more specifically, the present invention relates to a solar panel drive and tilt mechanism for rotating a large array of solar panels that includes a stow strategy having a stow-and-lock system integrated into the array support piers.

2. Background Discussion

For years drive mechanisms have been employed to rotate and align solar panel arrays. However, most of the drive mechanisms in the prior art have not been designed to use a single drive unit to move large arrays with multiple rows of panels. Extremely large multi-megawatt solar power stations are now being planned and built, so the need for efficiently driving large arrays has become an important and necessary part of the solar power system.

In general, solar photovoltaic panels for large scale energy production comprise a collection of photovoltaic cells configured in rectangular patterns. A number of panels are typically mounted level with one another on top of support structures with minimal spacing between panels. This economizes on space and maximizes solar collection efficiency.

Further, solar panel arrays are typically mounted to optimize the sunlight striking their surfaces during daylight hours. In order to further improve solar collection efficiency, drive mechanisms have been employed to keep the panel surfaces in a perpendicular (normal) orientation relative to the direction of travel of the sun's rays.

There are a number of prior art drive systems designed to track the sun with a solar panel array. These drive mechanisms generally tilt the solar panel arrays by moving the structures upon which the panels are mounted. Both horizontal and vertically driven systems have been utilized for this purpose. Although numerous panel movement mechanisms have been employed, they are generally ill-suited for using a single drive system to rotate large arrays (i.e., those having 1000 or more panels). Accordingly, the installation and commissioning of large solar panel array tracking systems using such drive mechanisms have been complicated and therefore costly.

A number of patents show tilt mechanisms for the movement of multiple panel arrays. Notable examples include:

U.S. Pat. No. 4,429,178 to Pridaux et al (1984), which shows a plurality of closely spaced solar panels mounted in pairs on opposite sides of a number of horizontally extending, co-linear torque tubes supported for rotation about their respective co-linear axes by a number of support posts. A drive assembly on one of the support posts is connected to a pair of torque tubes for simultaneously rotating these and the other torque tubes in a solar tracking mode.

U.S. Pat. No. 5,228,924 to Barker et al (1993) discloses a mechanical solar module support structure for pivotally more than one photovoltaic panel in a planar array. The system uses a single mechanism to simultaneously change the angle of declination of the array by the same amount. The system includes at least two side-by-side coplanar panels, a pivot shaft extending transversely of the side-by-side panels, at least two supports spaced apart lengthwise of the shaft, mounting apparatus for mounting the pivot shaft to the supports, connectors for connecting the panels to the pivot shaft so that the panels can pivot about the longitudinal axis of the shaft, a mechanical coupling linking the panels together to form a unified flat array, and a drive motor for mechanically pivoting the unified array about the axis and for locking the array against pivotal movement when the motor is off.

The systems shown in each of the '924 and the patents depend on a single spine to pivot and support the solar panels. This necessitates additional structural cross-members to provide adequate support for the panel arrays due to gravity and to withstand high winds. The additional cross-members increase the spacing or height of the panels above the pivot axis. Consequently, the side forces on the panels due to wind loading create substantial torsional forces that must be withstood by the rotational drive mechanism, and this leads to a need for much higher drive forces.

U.S. Pat. No. 6,058,930, to Shingleton, teaches a drive mechanism for rotating solar arrays using a single torque tube. The disadvantage of this approach is that the torque tube and the bearings at the support posts must be quite large to transmit the torque. The '930 patent also teaches driving multiple rows of panels simultaneously utilizing a single ram drive mechanism. The problem with this approach is that the ram force required to drive a large number of panels creates a substantial side force at the ram base. This creates the need for substantial anchoring or large pedestals to withstand the large side load produced by the ram.

Another liability of prior art drive systems is that they create challenges for field installations. For instance, using the prior art systems, vertical adjustments of the arrays have been difficult and limited. This problem is most prevalent for arrays mounted in a soil environment where the principal means of support is driven pilings. Because of the variations in piling heights it is necessary to provide vertical positioning and holding devices to adjust the solar panel arrays to the required height. This is a time-consuming and expensive process. Screw adjustment mechanisms may be used, but they are also expensive for the large diameter posts needed to support multiple panels.

In addition to the foregoing, it is well known that large solar panel arrays and array tracker systems can be subjected to large wind loads. In consequence, solar array designers and engineers have implemented stow and lock strategies similar to those implemented in antenna designs. The fundamental concern is to provide a stow strategy that places solar panels in a position in which the array structure can tolerate the load while also orienting the effective solar collection area to the incident solar radiation for optimal operation, at least when such objectives can be pursued concurrently. With unlimited resources, any system can be built sufficiently robust to eliminate the need to balance such interests. But as a practical matter, such a balancing is economically imperative, and systems are generally designed with sufficient structural integrity to operate under most conditions encountered in the installation environment, but while also having a stow and lock strategy that will enable protection when sunlight is insufficient or when wind loads are too severe for safe operation.

The usual strategy adopted by most designers uses a 0 (zero) degree stow position; i.e., a position in which the plane of the solar panels is essentially parallel to the horizon. The rationale underlying such designs is that the load imposed on the panels is theoretically zero, as air moves substantially even over the upper and lower surfaces of the panels. However, winds rarely move perfectly level with the horizon, and wind loads imposed on the solar panels in a panel array are almost never zero. Panels installed on uneven or sloped terrain, near large structures, or in areas with colliding wind conditions, are invariably subjected to significant wind stress.

Further, large solar panel array tracker systems invariably include motorized drive systems that coordinate movement of the panels (setting the panels populating each array row), and such systems using a stow strategy of 0 degrees typically rely heavily on the motorized rotational drive system to resist the compounding moment forces through the rotational supports as they build through each system bay. This strategy therefore requires the motorized rotational drive system to resist all the forces of the additive tributary area of a wing or row of panels.

It would be desirable, therefore, to provide a solar panel array tracking system that transmits moment forces of the array directly to support members immediate to the particular array tributary area, thereby reducing or eliminating the need for the driveline and rotational supports to bear the cumulative loads from large array wings and rows.

The foregoing background discussion covers the art of which the present inventors are aware. Reference to, and discussion of, the above-identified patents is intended to aid in discharging Applicants' acknowledged duty of candor in disclosing information that may be relevant to the examination of claims to the present invention. However, it is respectfully submitted that none of the above-indicated patents disclose, teach, suggest, show, or otherwise render obvious, either singly or when considered in combination, the invention described and claimed herein.

### BRIEF SUMMARY OF THE INVENTION

The present invention is a new and improved solar power tracking system for optimally aligning a plurality of electricity generating solar panels comprising a solar panel array. A first and principal object of the present invention is to provide a method and apparatus for rotational movement of a solar panel array to optimally align for capturing and utilizing solar energy. The inventive array tracker system has a stow strategy that utilizes a stow/lock system built into the array support piers. A stopper is mechanically and structurally incorporated into the support piers so that the panels are stopped and fully supported at approximately 45 degrees, and the stopper ensures that moment forces of the array are transmitted directly to the immediate support members. Forces additive in a 0 (zero) degree stow strategy are now instead directly supported by the driven support members (e.g., piers) immediate to the tributary area. The driveline, locking dampers, and rotational supports are thus no longer required to resist the cumulative forces from an entire wing and row.

While the system is particularly well suited for use in solar panel array trackers, use with any kind of payload oriented relative to the sun using a solar tracker system is contemplated. Such payloads may include antennas, telescopes, solar reflectors and lenses, solar photovoltaic systems, solar thermal systems, and so forth.

There has thus been broadly outlined the more important features of the invention in order that the detailed description that follows may be better understood, and in order that the present contribution to the art may be better appreciated. Additional objects, advantages and novel features of the invention will be set forth in part in the description as follows, and in part will become apparent to those skilled in the art upon examination of the following. Furthermore, such objects, advantages and features may be learned by practice of the invention, or may be realized and attained by means of the instrumentalities and combinations particularly pointed out in the appended claims.

Still other objects and advantages of the present invention will become readily apparent to those skilled in this art from the following detailed description, which shows and describes only the preferred embodiments of the invention, simply by way of illustration of the best mode now contemplated of carrying out the invention. As will be realized, the invention is capable of modification in various obvious respects without departing from the invention. Accordingly, the drawings and description of the preferred embodiment are to be regarded as illustrative in nature, and not as restrictive.

### BRIEF DESCRIPTION OF SEVERAL VIEWS OF THE DRAWINGS

The invention will be better understood and objects other than those set forth above will become apparent when consideration is given to the following detailed description thereof. Such description makes reference to the annexed drawings wherein:

FIG. 1 is a drawing of the solar panel tracking system showing a representative two rows of an array and the drive system associated with the two rows;

FIG. 2 is a drawing of the drive actuator illustrating how it transmits linear force to the rotational actuators in each row;

FIGS. 3 and 4 illustrate how the linear force from the actuator is transformed into rotational force at each row;

FIG. 5 shows the underside of the solar array for a typical row and illustrates how the two bar structure pivots the array on the support posts;

FIGS. 6a and 6b illustrate the vertical positioning device used at each support post for the solar array and for the ram structural support;

FIGS. 7A and 7B show the appartus with which the solar panels are attached to the support rails;

FIG. 8 is an upper perspective view showing two bays forming a portion of an array and a motorized drive system disposed between the two bays;

FIG. 9 is a side view in elevation showing details of the pivot assembly disposed in the center of each system bay;

FIG. 10 is side view in elevation showing the panel support assembly atop a vertically disposed array support post;

FIG. 11 is a lower perspective view showing a panel mounted on one side of a pivot assembly;

FIG. 12 is an upper perspective view of a rotational support cradle assembly; and

FIG. 13 is an upper perspective view of the pivot bracket assembly onto which the rotational support cradle assembly is mounted.

### DETAILED DESCRIPTION OF THE INVENTION

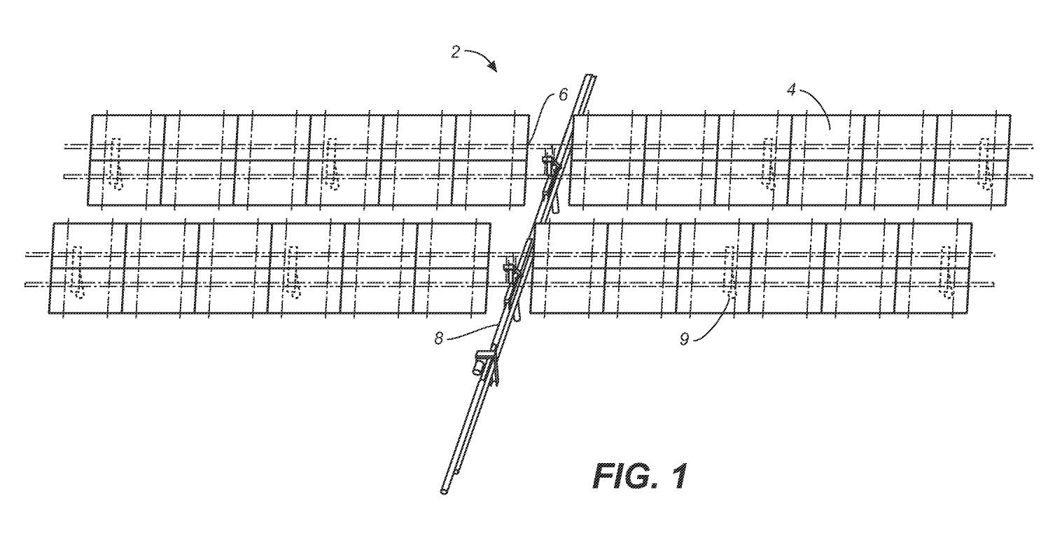

Referring first to FIGS. 1 through 7B, there is illustrated a new and improved solar power sun tracking system. FIG. 1 shows a first preferred embodiment of the solar tracking system of the present invention. The solar panel array 2 generally includes one or more rows of solar panels 4 mounted on a rotatable support structure 6 positioned with a rotation axis A for each panel oriented north and south. The drive system 8 is positioned on an east west axis perpendicular to the rotation axes of the solar panels in the array rows.

The solar panels in the array are disposed in the same pattern on each side of the drive system. This array pattern is repeated for additional rows north and south of the initial row. A series of support posts 9, which in general consists of vertical pilings driven into the ground and related connection hardware are typically used for the support of the array 2.

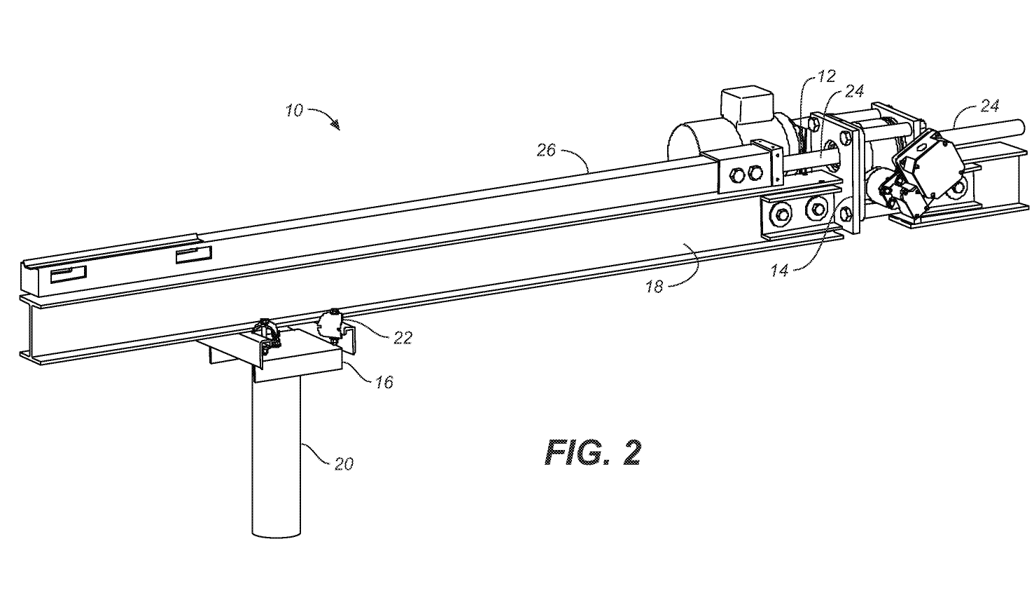

FIG. 2 shows a preferred drive system 10 for the solar panel array tracking system of the present invention. The drive system includes one or more motorized rams 12, each mounted to a ram support 14 which is in turn mounted to a ram support beam 18, which is disposed substantially horizontally. The ram support beam 18 is typically attached to support bases 16 with clamps 22 or welds, and the support bases are each attached to a piling or post 20 drive into the ground or otherwise securely mounted on a suitable mounting surface, such as a building roof, and preferably disposed substantially vertically. The motorized ram 12 has dual-sided drive shafts 24 that allow it to provide reciprocating force on opposing sides. That is, the motorized ram will simultaneously push the panel array in front of it and pull the panel array behind it, thereby reducing the number of rams needed to drive the solar array. It also reduces by half the maximum shaft force imposed on the shaft if the ram were located at either end of the rows. The drive shafts may be coupled to a reciprocating drive tube 26, but reference to the drive shaft herein contemplates both the shaft driven directly by the motorized ram and any physical extensions thereof, including tubes such as drive tubes.

In this preferred embodiment the drive shaft support beam 18, which can be any form of structural beam or tubing, is connected directly to the base structure of the ram 12. The drive shaft support beam 18 is the principal structure against which forces exerted by the drive shaft are imposed, and because the drive shaft and ram are each mounted to the support beam, external side loads are virtually eliminated. The drive shaft support beam 18 also functions as a wire and conduit support as well as a support for the ram shaft.

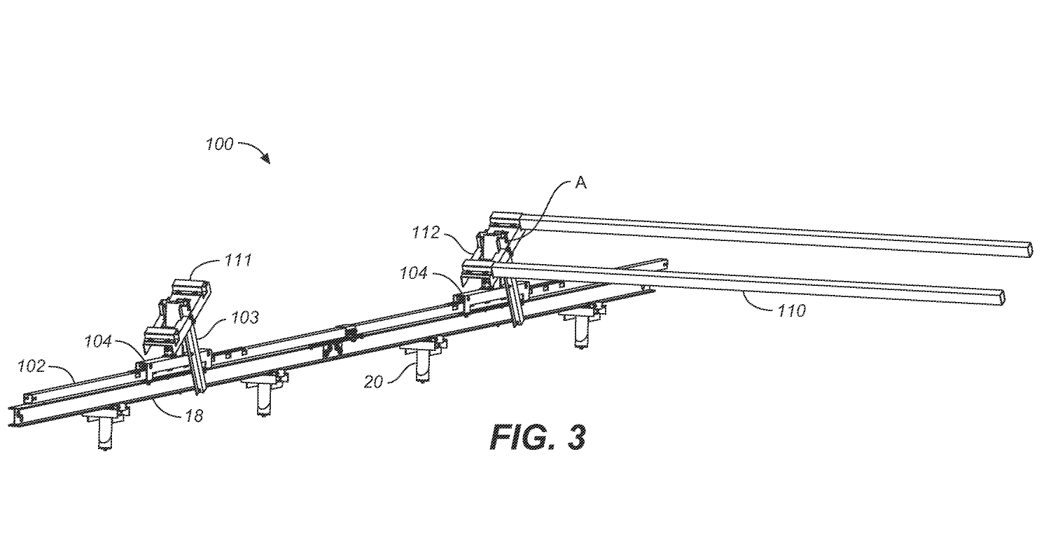

Referring now to FIGS. 3 and 4, the rotational drive system 100 includes a ram 12 that reciprocates (pushes or pulls) one or more drive tubes 102 in a horizontal direction from one or both sides of the ram 12. This horizontal movement is parallel to the longitudinal axis of the support beam and is translated into rotational movement by means of a drive arm 103 which pivots about the axis of rotation A for the solar panel array. A pivot support post platform 104 provides the stationary structure on which the pivot support post 105 is affixed and from which the drive arm 103 rotates. The pivot support post platform also transfers the horizontal force imparted to it back to the drive shaft support beam 18 by means of the pivot support post 104. The combination of the pivot support post platform 104, pivot support post 105, and drive shaft support beam 18 creates the reacting structure for transferring the drive shaft force back to the ram. This combination can also consist of a coaxial structure with the drive shaft positioned in the center and a cylindrical or square tube or pipe surrounding the drive shaft. The drive tube 102 (ref. no. 26 in FIG. 2) moves horizontally between the upper and lower stationary components, i.e., the pivot support post platform and post and the drive shaft support beam 18, respectively, by means of a roller bearing 108 mounted to the drive tube 102 by means of a drive pin 107. This reduces frictional resistance. Sliding bearings or linear bearings can be substituted for the roller bearing. As the drive shaft/reciprocating drive tube 102 translates horizontally, it swings or rotates the drive arm 103 by means of the drive pin 107 that extends into a drive arm channel 109. This drive pin 107 is also connected to a roller bearing inside the drive arm 103 that rolls outwardly in the channel towards the end of the drive arm 103 as the drive arm rotates up from its vertical position. This rolling action provides virtually frictionless movement of the drive arm 103 as it is rotated about the solar array axis. Alternatively linear bearings or sliding bushings can be used in the drive arm 103 for this invention. Rotational support tubes 110 affixed to the underside of the solar panels are mounted in tubular clamps 111 disposed on the shoulders of a mounting rail support bracket 112 on each side of the drive arm 103. The rotational motion of the drive arm 103 is thus transferred directly to the solar array.

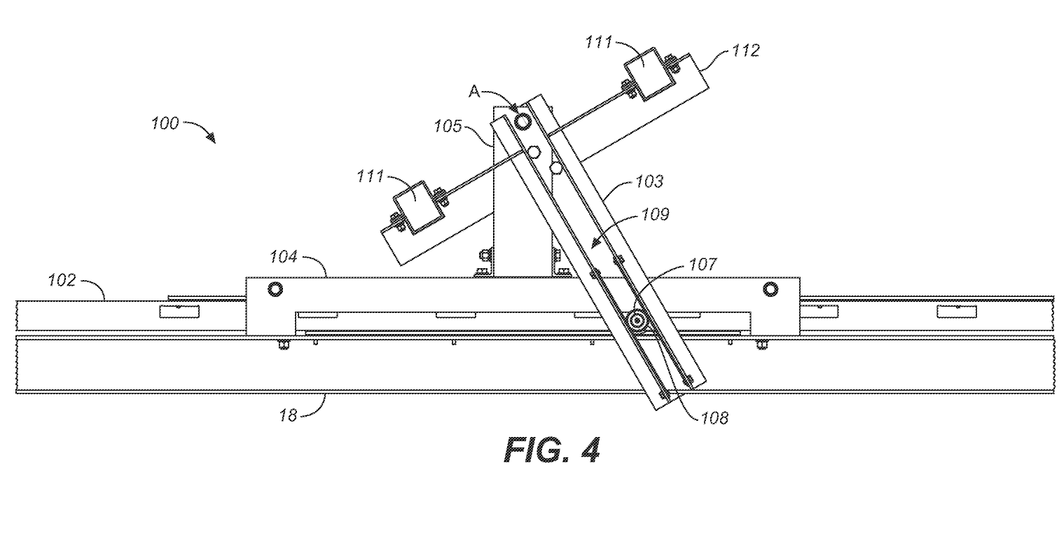

Referring now to FIG. 5, in the preferred embodiment of the solar panel array sun tracking system of the present invention, the lateral mounting structure 200 of the solar panel array allows a group of modules or side-by-side panels 202 to be deployed to each side of a support beam, generally with pairs of side-by-side panels mounted in series in an end-to-end fashion. Because of the lengths of the panels and their support structures, and because the panels are rotated and adjusted in coordination, substantial support structure is required, and in the preferred embodiment this comprises two or more panel mounting rails 204 (ref. no. 110 in FIG. 3), shown herein as substantially square tubes. Other support structure can be provided, including rectangular tubes, round tubes, pipe, I-beams, and channels. The mounting rails 204 are affixed to plurality of support cradles 208 which are attached to support posts 206 anchored into the ground at a nominal spacing of 12 to 17 feet. The distance between support posts can be varied over a wider range if the panel mounting rails sized accordingly. The panel mounting rails 204 are pivotally mounted to the support posts 206 (09 in FIG. 1) by means of a support cradle 208 and splice clamps 212 that clamp the mounting rails to the support cradle 208. The support cradle 208 is hinged at the support posts by means of a pivot pin 210 that aligned with the solar panel axis of rotation A.

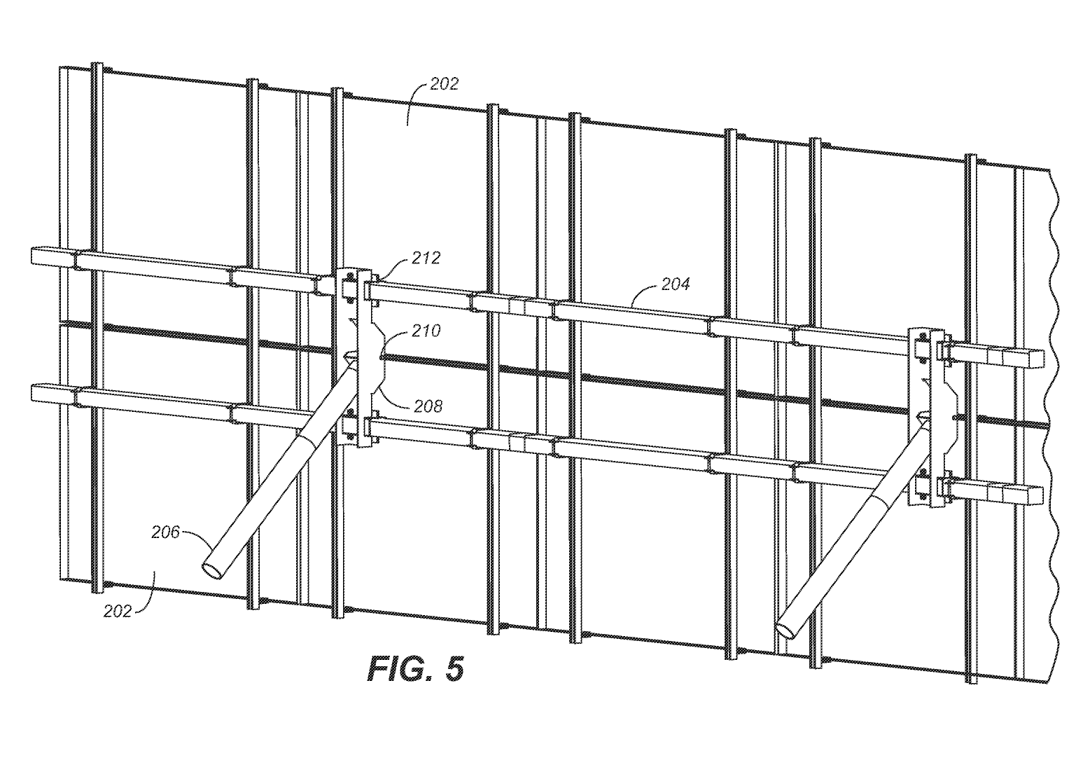

Referring now to FIG. 6, the support beams of the present invention are preferably provided with a novel vertical adjustment mechanism 300. This mechanism is disposed within and located at each of the support posts to provide for independent and easy vertical adjustability of each post. The mechanism comprises a tube pair 302 with a shared angular seam and a cinch plate 304, both of which are inserted into the support post tube 310. A pivot bracket 306 is mounted on top. Once the tube pair 302 is positioned at the appropriate height the cinch bolt or threaded rod 308 is tightened creating an offset within the support post 310 which in turn holds the array at the desired position and provides the vertical support needed for the array.

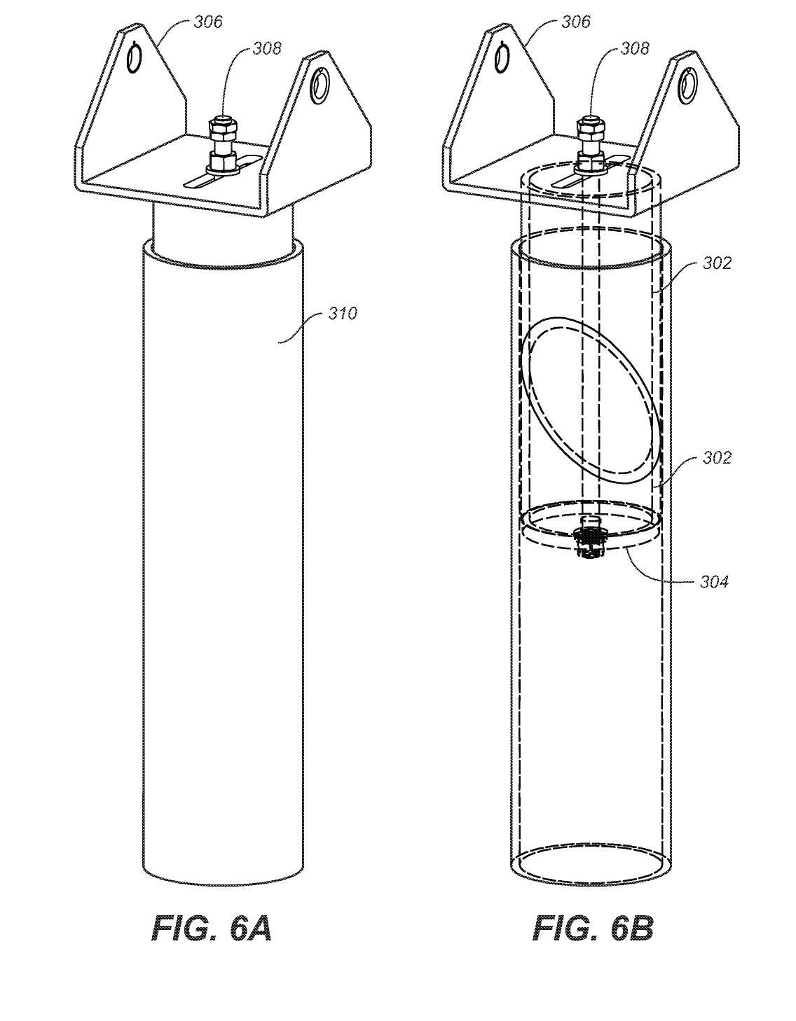

The solar panel mounting apparatus of the preferred embodiment of the inventive solar panel array sun tracking system is shown in FIG. 7. Each solar panel pair 400 is mounted to two or more cross rails 404 which in turn are mounted to the panel mounting rails 406 (ref. nos. 204 in FIGS. 5 and 110 in FIG. 3). This structural sandwich of panels 402, cross rails 404, and panel mounting rails 406 creates the structural rigidity needed to withstand winds exceeding 100 miles per hour. The cross rails 404 are typically notched to provide fast and accurate positioning of the rails on the panel mounting rails 406. The cross rails 404 are clamped to the panel mounting rails 406 (ref. no. 204 in FIG. 5) with pairs of anchor clamps 412 that are cinched together by means of standard nuts and bolts. Each solar panel 402 is connected to the cross rails 404 with industry standard T Clips and End Clips 408 and 410. There are two or more cross rails 404 that hold each panel pair 400 and provide a 4 point contact to insure proper support. FIG. 7 illustrates the typical attachment method for T Clips and End Clips 408 and 410 to the panel 402.

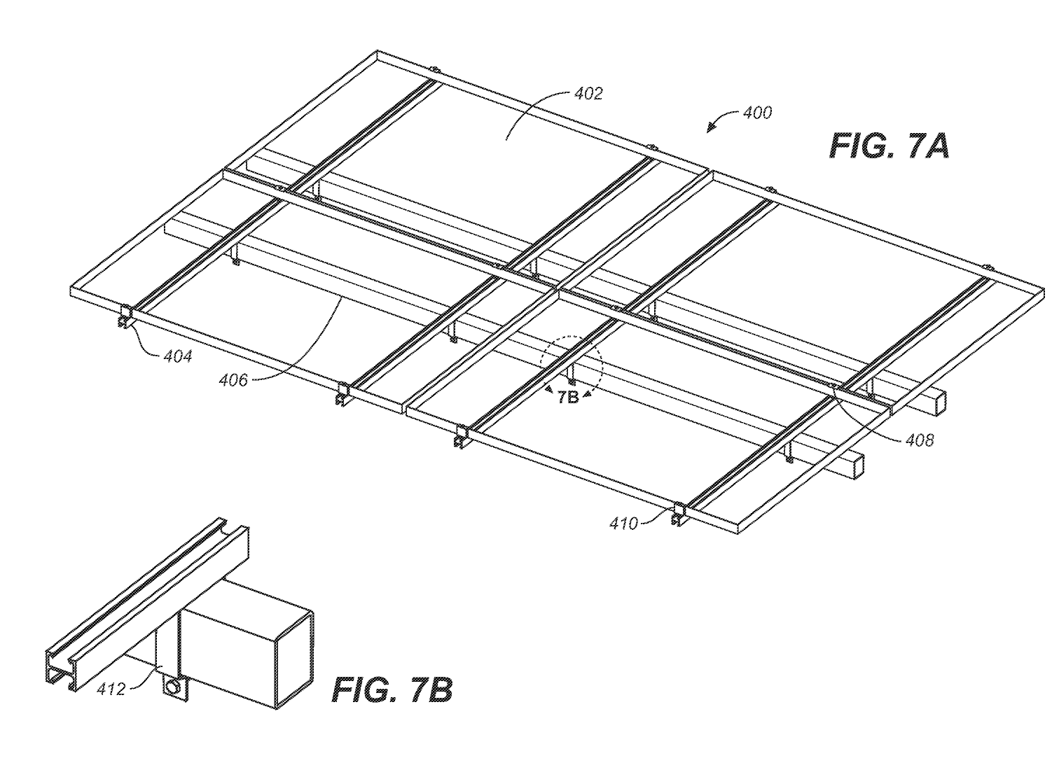

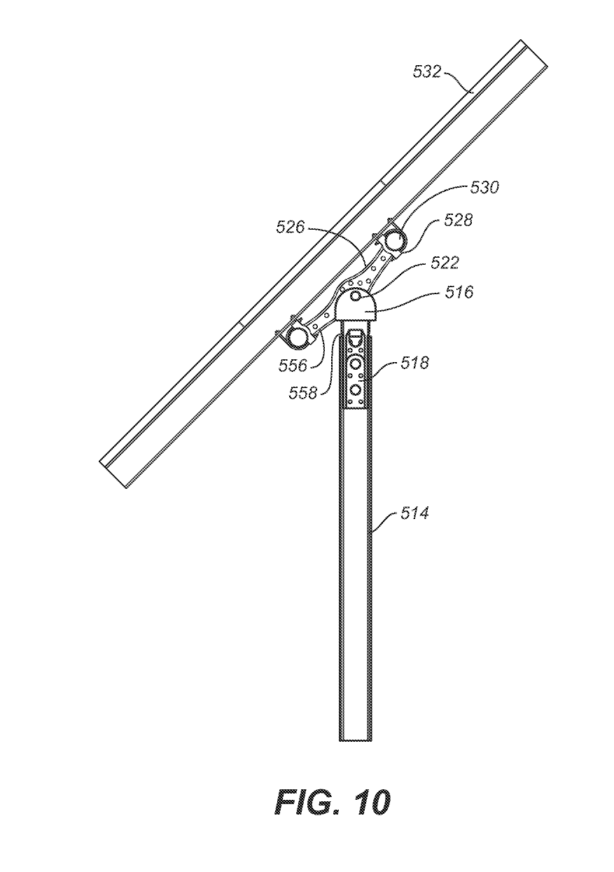

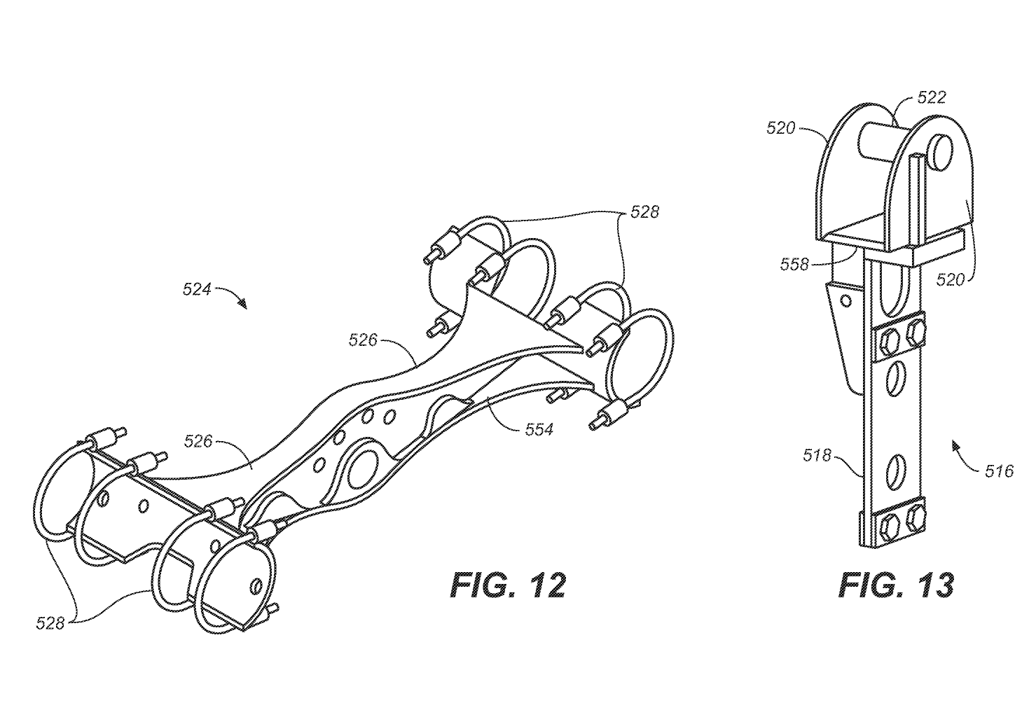

Referring next to FIGS. 8 through 13, wherein like reference numerals refer to like components in the various views, there is illustrated therein a new and improved solar panel array tracker system, generally denominated 500 herein, especially well-suited for use in a solar power sun tracking system of the kind described above and illustrated in FIGS. 1-7B.

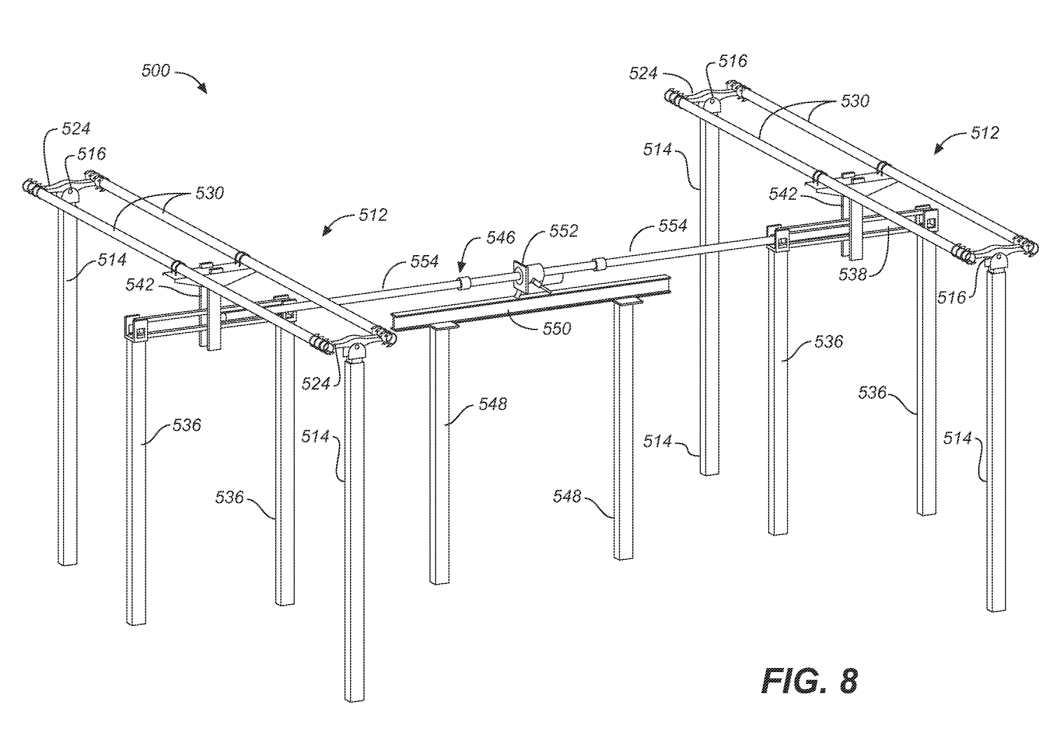

The inventive stow-and-lock system for a solar panel array tracking system 500 uses a motorized rotational drive system to move each panel array from +45 degrees to −45 degrees. Each system bay 512 includes two or more vertically disposed array posts 514, each having a pivot bracket assembly 516 bolted to its upper end (for details see FIGS. 9-10, and 13). The pivot bracket assembly includes a bolting plate portion 518 for connection to the array posts and two spaced-apart shoulders 520, between which is disposed a horizontally oriented pivot pin 522.

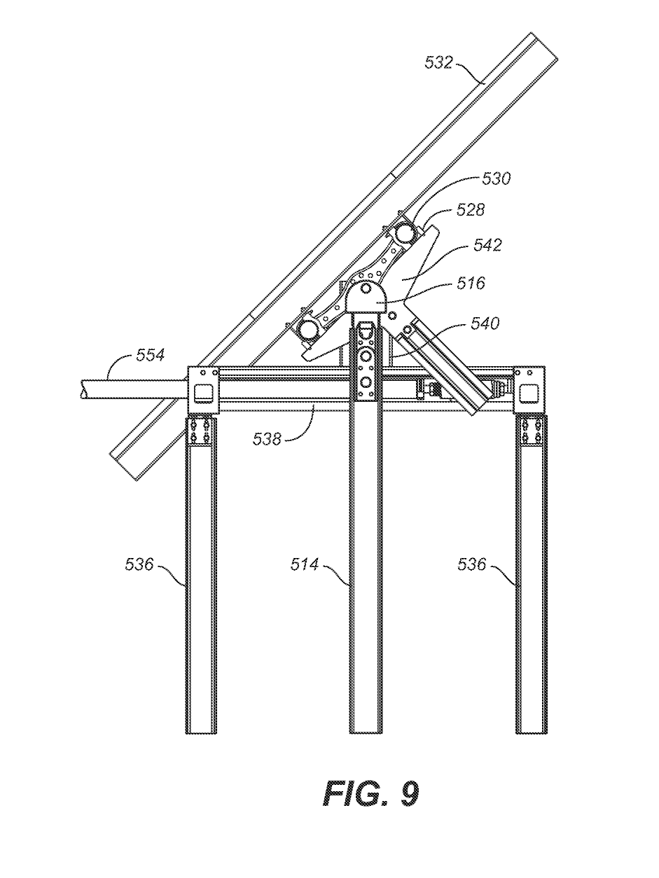

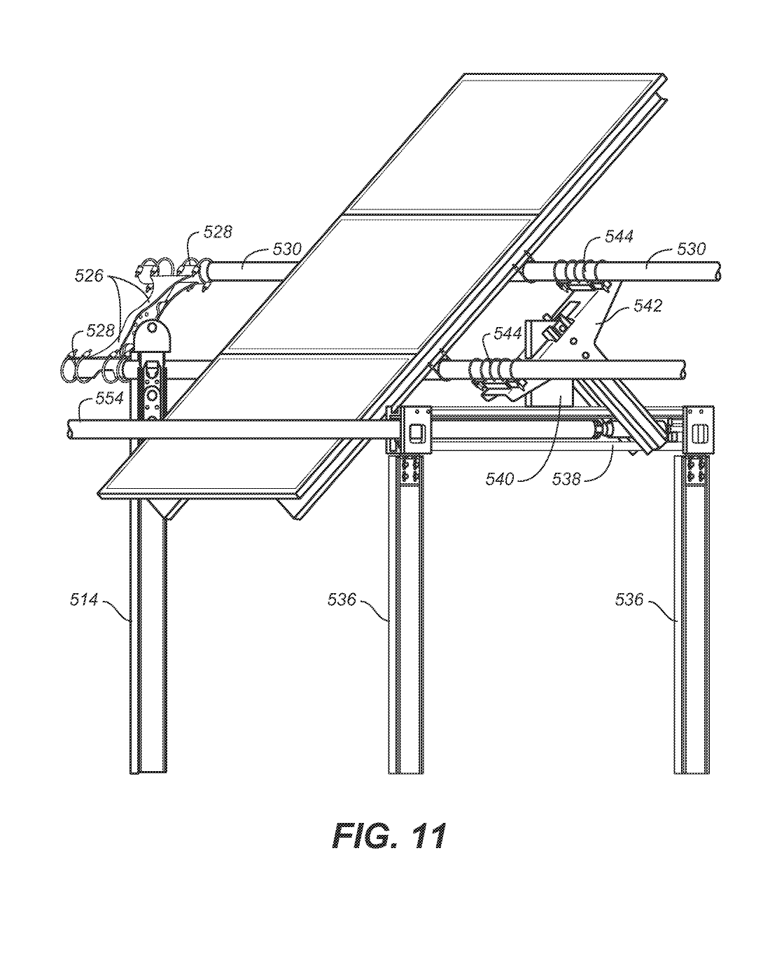

Pivotally coupled to each pivot bracket assembly is a rotational support cradle assembly 524, shown in isolation in FIG. 12, and incorporated into the system shown in FIGS. 9-10. The rotational support cradle assembly includes a central through hole through which pivot pin 522 is disposed, and two arms 526, each having a plurality of clamps 528 for clamping support rails 530. Solar panels 532 are mounted on the support rails.

In the center of each bay is a pivot assembly 534 comprising two piers 536 having a pivot post support beam 538 with ends bolted to the upper ends of the piers and thus disposed between the piers. A pivot post 540 is mounted on the support beam 538 and a drive arm 542 is pivotally mounted on the pivot post. The drive arm is connected to the support rails 530 with clamps 544.

Driving the panels mounted in each bay is a motorized drive system 546, including one or more motor mount supports 548 supporting a motor mount platform 550 with a motor 552 (such as a jack screw motor) mounted thereon. The motor is operatively coupled to drivelines 554 extending in one or more directions, which are, in turn, operatively coupled to the drive arms 542, such that horizontal translation of the drivelines effects simultaneous pushing or pulling of the respective drive arms coupled to one or the other side of the motor in a manner arm support beam in a manner described in co-pending U.S. patent application Ser. No. 12/088,121, issued U.S. Pat. No. 8,273,978, incorporated in its entirety by reference herein.

The pivot bracket assembly can be sized and configured to stop rotation of the drive arm when the panel array reaches a predetermined angle in relation to the horizon, which is also a predetermined angle in relation to the vertical disposed array posts. Thus, for instance, and as seen in the views, when the motor positions the panels at either the +45 to −45 degrees positions, the undersides 556 of the many arms 526 of the system engage the bases 558 of the pivot bracket assemblies 516 and/or the top of the vertically disposed array posts 514, such that the following components bear all the loads from wind forces: (1) pivot pin 522; (2) the motorized rotational drive system 546; and arm 526 of rotational support cradle 524. Those with skill will appreciate that the range of rotational movement can be altered simply by raising pivot pin 522 in relation to base 558, or alternatively by modifying the shape of the underside 556 of arm 526. Thus, it will be appreciated that the possible range of motion could be made adjustable by providing a plurality of vertically separated holes in the shoulders 520 of the pivot bracket assembly 516. Then, to increase or decrease the possible range of motion, the horizontally oriented pivot pin 522 can be moved up or down, respectively, for placement either higher or lower in relation to the vertical post and the pivot bracket assembly base.

As will be appreciated from the foregoing, if the motor and drivelines were removed and disconnected from the arms, the array panels would rotate to approximately 45 degrees, and at that point the pane rotation would stop by virtue of the contact between the arm of the rotational support cradle and the base of the pivot bracket assembly. This distinguishes the present invention from known array tracker systems, which depend almost entirely on the motor and drive elements to lock the array in a stow position, and which would permit rotation of the array to a position of approximately 90 degrees were the motor and drive elements removed.

Having fully described several embodiments of the present invention, many other equivalents and alternative embodiments will be apparent to those skilled in the art. These and other equivalents and alternatives are intended to be included within the scope of the present invention.

Therefore, the above description and illustrations should not be construed as limiting the scope of the invention, which is defined by the appended claims.

What is claimed as invention is:

1. A stow-and-lock system for a solar panel array sun tracking system, said sun tracking system including a motorized rotational drive system for moving a plurality of solar panels in an array through a range of positions, said stow-and-lock system comprising:
a plurality of vertically disposed array posts;
a pivot bracket assembly mounted to the top of each of said vertically disposed array posts, said pivot bracket assembly including a pivot pin positioned above said top of said array post; and
a rotational support cradle assembly pivotally coupled to said pivot pin, said rotational support cradle assembly having a through hole in which said pivot pin is disposed, and two arms, each of said arms having an underside and a plurality of clamps for clamping support rails disposed between at least two of said vertically disposed array posts, said support rails connected to one or more solar panels, said pivot bracket assembly sized and configured to pivot and stop when the panel array reaches a predetermined angle in relation to the horizon;
wherein when the motorized drive system has moved the solar panels at either end of the range of possible positions, said undersides of said arms of said support cradles engage at least one of said pivot bracket assemblies, such that the loads from wind forces are borne by said pivot pins, said arms, and said motorized rotational drive system.

2. The stow-and-lock system of claim 1, wherein said pivot bracket assembly includes a base and two spaced-apart shoulders having a through hole for placement of said pivot pin.

3. The stow-and-lock system of claim 2, wherein said underside of said arms engages said base when the motorized rotational drive system is at either end of the range of possible positions of the array.

4. The stow-and-lock system of claim 2, wherein said pivot bracket assembly includes a plurality of spaced-apart vertically oriented holes for adjustable placement of said pivot pin.

5. The stow-and-lock system of claim 1, wherein said pivot bracket assembly includes a plurality of spaced-apart vertically oriented holes for adjustable placement of said pivot pin.
